(19) United States
(12) Patent Application Publication
(10) Pub. No.: US 2026/0324523 A1
(43) Pub. Date: Oct. 15, 2026

(54) SEMICONDUCTOR PACKAGE INCLUDING SUPPORT WIRE

(71) Applicant: Samsung Electronics Co., Ltd., Suwon-si (KR)

(72) Inventors: Wooju Kim, Suwon-si (KR); Junyun Kweon, Suwon-si (KR); Haemin Park, Suwon-si (KR); Kangil Yun, Suwon-si (KR); Dayoung Cho, Suwon-si (KR); Jinwook Hong, Suwon-si (KR)

(21) Appl. No.: 19/433,241

(22) Filed: Dec. 26, 2025

(30) Foreign Application Priority Data
Apr. 10, 2025 (KR) 10-2025-0046589

(51) Int. Cl. H10W 90/00; H10W 72/50; H10W 74/10; H10W 90/20; H10W 90/24; H10B 80/00; H10D 80/30; H10W 72/00

(52) U.S. Cl. CPC H10W 90/752; H10W 72/5453; H10W 72/5473; H10W 74/117; H10W 74/121; H10W 90/24; H10W 90/275; H10W 90/754; H10B 80/00; H10D 80/30; H10W 72/884; H10W 90/732; H10W 90/734

(57) ABSTRACT

A semiconductor package includes a substrate including a bonding pad, a plurality of stack chips stacked on the substrate, a top chip disposed on the plurality of stack chips and including an edge protruding outwardly of the plurality of stack chips, a first support pad disposed on the top chip and adjacent to the edge, a second support pad disposed on one of the plurality of stack chips or on the substrate and spaced apart from the first support pad in an opposite direction to the edge, a support wire connecting the first support pad to the second support pad, and a bonding wire connecting a connection pad of each of the stack chips and the top chip to the bonding pad.

### CROSS-REFERENCE TO RELATED APPLICATION(S)

This application claims benefit of priority to Korean Patent Application No. 10-2025-0046589 filed on Apr. 10, 2025, in the Korean Intellectual Property Office, the disclosure of which is incorporated herein by reference in its entirety.

### BACKGROUND

The present inventive concept relates to a semiconductor package.

With the development of the electronics industry, demand for high functionality, high speed, and miniaturization of electronic components has increased. In accordance with this trend, a semiconductor packaging technology of stacking multiple semiconductor chips in a single package has been developed. An increase in the number of stacked semiconductor chips may lead to problems, such as sagging and cracks in an upper semiconductor chip.

### SUMMARY

An aspect of the present inventive concept is to provide a semiconductor package having improved reliability.

According to an aspect of the present inventive concept, a semiconductor package includes: a substrate including first bonding pads, the substrate including a first edge and a second edge which are spaced apart from each other in a horizontal direction in a plan view; a plurality of first chips stacked on the substrate; a second chip stacked on the plurality of first chips and including a third edge protruding away from the plurality of first chips in the horizontal direction in the plan view; a second bonding pad disposed on the second chip and adjacent to the third edge, the second bonding pad being closer to the second edge than to the first edge in the horizontal direction in the plan view; a third bonding pad disposed on one of the plurality of first chips or on the substrate and spaced apart from the second bonding pad in the horizontal direction in the plan view, the third bonding pad being closer to the first edge than to the second edge in the horizontal direction in the plan view; a first bonding wire in contact with the second bonding pad; and second bonding wires, each of the second bonding wires electrically connected to a corresponding one of the first bonding pads. The first bonding wire is directly connected to the third bonding pad, each of the plurality of first chips includes a fourth bonding pad, and the second bonding wires are respectively electrically connected to the fourth bonding pads.

According to an aspect of the present inventive concept, a semiconductor package includes: a substrate including a bonding pad; a plurality of semiconductor chips stacked on the substrate and respectively including a connection pad; a bonding wire connecting the connection pad to the bonding pad; a combination of the plurality of semiconductor chips and the substrate include a pair of support pads; a support wire connecting the pair of support pads; and a molding layer covering the plurality of semiconductor chips, wherein the pair of support pads include: a first support pad at a first height level relative to the substrate; and a second support pad at a second height level lower than the first height level relative to the substrate.

According to an aspect of the present inventive concept, a semiconductor package includes: a substrate; a plurality of stack chips stacked on the substrate; a top chip disposed on the plurality of stack chips and including a first overhang portion; a first support pad positioned on the first overhang portion of the top chip; a second support pad disposed on one of the plurality of stack chips or on the substrate; a support wire connecting the first support pad to the second support pad; and a bonding wire electrically connecting the plurality of stack chips and the top chip to the substrate.

According to an aspect of the present inventive concept, a method of manufacturing a semiconductor package includes: attaching a plurality of stack chips on a substrate; attaching a top chip on the plurality of stack chips, wherein the top chip includes an overhang edge protruding outwardly from the plurality of stack chips and a first support pad adjacent to the overhang edge, and at least one of the substrate or the plurality of stack chips includes a second support pad spaced apart from the first support pad in an opposite direction to the overhang edge; and forming a support wire connecting the first support pad to the second support pad, wherein the support wire is primarily bonded to the first support pad and secondarily bonded to the second support pad.

According to an aspect of the present inventive concept, there is provided a method of manufacturing a semiconductor package, wherein the plurality of stack chips and the top chip are stacked such that respective bonding sides thereof alternately face both (or opposite) ends of the substrate, and the bonding wire connecting the plurality of stack chips to the substrate is formed before the support wire.

According to an aspect of the present inventive concept, there is provided a method of manufacturing a semiconductor package, wherein the bonding wire connecting the top chip to the substrate is formed after the support wire is formed.

According to an aspect of the present inventive concept, there is provided a method of manufacturing a semiconductor package, wherein the plurality of stack chips and the top chip are stacked such that respective bonding sides thereof face one end of the substrate, and the bonding wire connecting the plurality of stack chips to the substrate is formed before or after the formation of the support wire.

### BRIEF DESCRIPTION OF DRAWINGS

The aspects, features, and advantages of the present inventive concept will be more clearly understood from the following detailed description, taken in conjunction with the accompanying drawings, in which:

FIG. 1A is a plan view of a semiconductor package according to an embodiment, and FIG. 1B is a cross-sectional view taken along line I-I’ of FIG. 1A;

FIG. 2A is a plan view of a semiconductor package according to an embodiment, and FIG. 2B is a cross-sectional view taken along line I-I’ of FIG. 2A;

FIG. 3A is a plan view of a semiconductor package according to an embodiment, and FIG. 3B is a cross-sectional view taken along line I-I’ of FIG. 3A;

FIG. 4A is a plan view of a semiconductor package according to an embodiment, and FIG. 4B is a cross-sectional view taken along line I-I’ of FIG. 4A;

FIG. 5 is a plan view of a semiconductor package according to an embodiment;

FIG. 6A is a plan view of a semiconductor package according to an embodiment, and FIG. 6B is a cross-sectional view taken along line I-I’ of FIG. 6A;

FIG. 7A is a plan view of a semiconductor package according to an embodiment, and FIG. 7B is a cross-sectional view taken along line I-I’ of FIG. 7A;

FIG. 8A is a plan view of a semiconductor package according to an embodiment, and FIG. 8B is a cross-sectional view taken along line I-I’ of FIG. 8A; and

FIGS. 9 to 15 are diagrams illustrating a method of manufacturing a semiconductor package according to an embodiment.

### DETAILED DESCRIPTION

Hereinafter, embodiments of the present inventive concept will be described with reference to the accompanying drawings. Unless otherwise specified, spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, terms, such as “upper portion,” “upper surface,” “lower portion,” “lower surface,” “side surface,” etc. are based on the drawings, and may vary in the directions in which components are actually arranged. Thus, the term “below” can encompass both an orientation of above and below. The device may be otherwise oriented (rotated 90 degrees or at other orientations) and the spatially relative descriptors used herein interpreted accordingly.

In addition, ordinal numbers, such as “first,” “second,” “third,” etc. may be used as labels for specific elements, steps, directions, etc., to distinguish various elements, steps, directions, etc., from each other. Terms that are not described using “first,” “second,” etc., in the specification may still be referred to as “first” or “second” in the claims. Additionally, terms referenced by a particular ordinal number (e.g., “first” in a particular claim) may be described elsewhere with a different ordinal number (e.g., “second” in the specification or other claims).

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

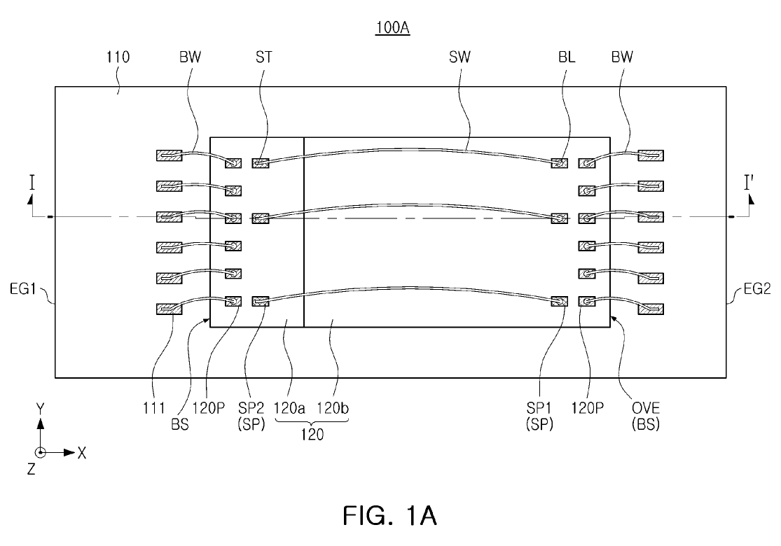

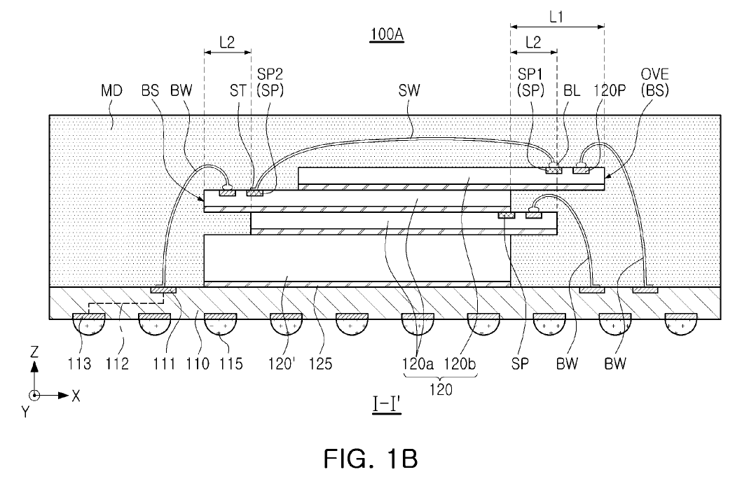

FIG. 1A is a plan view of a semiconductor package 100A according to an embodiment, and FIG. 1B is a cross-sectional view taken along line I-I’ of FIG. 1A.

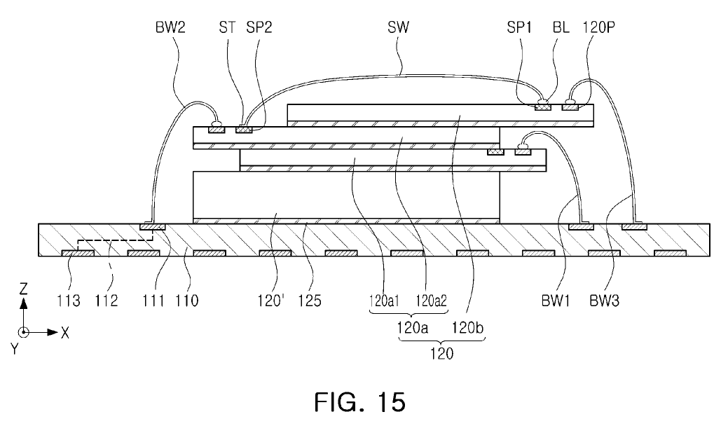

Referring to FIGS. 1A and 1B, the semiconductor package 100A of an embodiment may include a substrate 110, a plurality of semiconductor chips 120, and support structures SP and SW. In embodiments, the support structures SP and SW may be configured to distribute a load (or mechanical stress) applied to an overhang portion of a top chip 120b. Accordingly, sagging and cracking of the top chip 120b may be prevented or suppressed and the reliability of the semiconductor package may be improved, for example, in the process of forming the third bonding wire BW3 as discussed later with reference to FIG. 15.

The substrate 110 may be a semiconductor package substrate including a printed circuit board (PCB), a ceramic substrate, a glass substrate, a tape wiring substrate, and the like. For example, the substrate 110 may be a double-sided PCB or a multilayer PCB.

The substrate 110 may include a bonding pad 111, a wiring 112, and a bump pad 113. The bonding pad 111 may be disposed on an upper surface of the substrate 110, and the bump pad 113 may be disposed on a lower surface of the substrate 110. Each of the bonding pads 111 and the bump pads 113 may be electrically connected through the wirings 112, though not shown in the drawings. The bonding pad 111, the wiring 112, and the bump pad 113 may include at least one metal or an alloy including two or more metals among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

For example, the substrate 110 may include a first edge EG1 and a second edge EG2 which are spaced apart from each other in a horizontal direction X in a plan view. The pads SP1 and 120p may be closer to the second edge than to the first edge in the horizontal direction X in the plan view. A group of the bonding pads 111 of the substrate 110 may be closer to the second edge EG2 than to the first edge EG1 in the horizontal direction X in the plan view. The group of the bonding pads 111 of the substrate 110 may be connected to the pads 120p of the top chip 120b.

Connecting bumps 115 may be disposed below the bump pads 113. The connecting bumps 115 may be electrically connected to a plurality of semiconductor chips 120 through the wiring 112 and/or bonding wires. The connecting bumps 115 may have a flip-chip connection structure having a grid array, such as a ball grid array, for example. The connecting bumps 115 may have a spherical or oval shape formed of a low-melting point metal, such as tin (Sn), indium (In), bismuth (Bi), antimony (Sb), copper (Cu), silver (Ag), zinc (Zn), lead (Pb), or alloys thereof (e.g., Sn-Ag-Cu). The connecting bumps 115 may be electrically connected to an external device, such as a module substrate or a system board.

Each of the plurality of semiconductor chips 120 may be a part of a semiconductor wafer on which an integrated circuit (IC) is formed. The semiconductor wafer may include, for example, a semiconductor element, such as silicon, germanium, or a semiconductor compound, such as silicon carbide (SiC), gallium arsenide (GaAs), indium arsenide (InAs), and indium phosphide (InP). For example, the semiconductor wafer may be singulated or sawed to form a plurality of semiconductor chips 120. The plurality of semiconductor chips 120 may be bare semiconductor chips without separate bumps or interconnection layers, but are not limited thereto, and may also be packaged-type semiconductor chips.

The plurality of semiconductor chips 120 may include or be nonvolatile memory semiconductor chips, such as flash memory, phase-change random access memory (PRAM), magnetoresistive random access memory (MRAM), ferroelectric random access memory (FeRAM), or resistive random access memory (RRAM), and/or volatile memory semiconductor chips, such as dynamic random access memory (DRAM) or static random access memory (SRAM). In some embodiments, the plurality of semiconductor chips 120 may include at least one logic chip, for example, a central processing unit (CPU), a graphics processing unit (GPU), a field programmable gate array (FPGA), an application processor (AP), a digital signal processor, an encryption processor, a microprocessor, a microcontroller, an analog-to-digital converter, an application-specific IC (ASIC), etc. The plurality of semiconductor chips 120 may include the same type of semiconductor chips, but are not limited thereto. According to an embodiment, the plurality of semiconductor chips 120 may include different types of semiconductor chips. For example, the plurality of semiconductor chips 120 may include a logic chip and a plurality of memory chips.

The plurality of semiconductor chips 120 may be electrically connected to the bonding pads 111 of the substrate 110 through the bonding wires BW. The bonding wire BW may electrically connect a connection pad (or bonding pad) 120P of each of the plurality of semiconductor chips 120 to the bonding pad 111 of the substrate 110. For example, as depicted in the drawings, each of the bonding wires BW may be in contact with a connection pad 120P of each of the plurality of semiconductor chips 120 and a bonding pad 111 of the substrate 110. The bonding wire BW may include, but is not limited to, gold (Au), silver (Ag), lead (Pb), aluminum (Al), copper (Cu), or alloys thereof. The connection pad 120P may include one of copper (Cu), nickel (Ni), titanium (Ti), aluminum (Al), or alloys thereof. The connection pads 120P may include a signal pad, a power pad, and a ground pad. For example, each of the connection pads 120P may be one of a signal pad, a power pad, and a ground pad. The signal pad may provide a transmission/reception path for various signals, such as data signals, address signals, etc., excluding ground signals, power signals, etc. A molding layer MD may be disposed on the substrate 110. The molding layer MD may cover the plurality of semiconductor chips 120 and the bonding wire BW. The molding layer MD may include an insulating resin including an inorganic filler, such as Ajinomoto build-up film (ABF), epoxy molding compound (EMC), etc.

The plurality of semiconductor chips 120 may be stacked on the substrate 110 in a vertical direction (a Z-direction). The plurality of semiconductor chips 120 may be attached to the substrate 110 or mutually attached (attached to one another) by an adhesive film 125. The adhesive film 125 may include a die attach film (DAF). The plurality of semiconductor chips 120 may include a plurality of stack chips 120a and the top chip 120b. The top chip 120b may be understood as the uppermost semiconductor chip among the plurality of semiconductor chips 120. The plurality of stack chips 120a may be understood as semiconductor chips vertically stacked between the top chip 120b and the substrate 110.

In embodiments, the plurality of semiconductor chips 120 may be horizontally offset so that each connection pad 120P is exposed to (or in contact with) the molding layer MD. For example, the plurality of semiconductor chips 120 may be stacked with horizontal offsets in alternating directions so that the plurality of first chips protrude, in the horizontal direction X or the reverse thereof, partially relative to adjacent ones of the plurality of first chips. Each of the plurality of semiconductor chips 120 may have a plurality of edges in a plan view. Among the plurality of edges, each of the plurality of semiconductor chips 120 may include an overhang edge OVE. For example, the uppermost top chip 120b may include an overhang edge OVE protruding outwardly (or away) from the plurality of stack chips 120a in the horizontal direction X. For example, the plurality of semiconductor chips 120 may be stacked such that one side (which may be referred to as a “bonding side BS” in the present specification) on which the connection pads 120P are arranged is disposed in a zigzag manner. The plurality of semiconductor chips 120 may be stacked such that the bonding sides BS of at least a group of the plurality of semiconductor chips 120 are arranged to form a zigzag pattern in a cross-sectional view taken along the horizontal direction X and the vertical direction Z. For example, the plurality of semiconductor chips 120 may be stacked such that one side BS of each of the plurality of semiconductor chips 120 alternately faces both (opposite) ends of the substrate 110. In this case, the bonding side BS of the top chip 120b may be the same as the overhang edge OVE. For example, the overhang edge OVE of the top chip 120b may be a bonding side BS of the top chip 120b. For example, the top chip 120b and the plurality of semiconductor chips 120 may be stacked with horizontal offsets in alternating directions so that the top chip 120b and the plurality of first chips protrude partially relative to adjacent ones of the plurality of first chips and the top chip 120b.The bonding side BS of the stack chip 120a disposed directly below the top chip 120b may face opposite to the overhang edge OVE of the top chip 120b. In addition, each of the plurality of stack chips 120a arranged in a zigzag pattern may include an overhang portion. In an embodiment, a length L1 of the overhang portion of the top chip 120b may be greater than a length L2 of the overhang portion of each of the plurality of stack chips 120a. In some embodiments, a spacer die 120’ may be disposed between the plurality of semiconductor chips 120 and the substrate 110. The spacer die 120’ may be a silicon dummy (e.g., silicon dummy chip) thicker than the semiconductor chips 120, but is not limited thereto. The spacer die 120’ may be attached to the substrate 110 by the adhesive film 125.

The support structures SP and SW may include at least one support connector including a pair of support pads SP and a support wire SW. A pair of support pads SP may be disposed on the plurality of semiconductor chips 120 or the substrate 110. The combination of the plurality of semiconductor chips 120 and the substrate 110 may include the pair of support pads SP. For example, the pair of support pads SP may be included in the plurality of semiconductor chips 120 and the substrate 110 such that, in some embodiments, the plurality of semiconductor chips 120 includes the pair of support pads SP, while in some embodiments, one of the plurality of semiconductor chips 120 includes one of the pair of support pads SP and the substrate 110 includes the other of the pair of support pads SP.

The support wire SW may extend over the plurality of semiconductor chips 120 to connect at least one pair of support pads SP. The support wire SW may be in contact with the pair of support pads SP. The pair of support pads SP may be electrically insulated from the connection pads 120P of the plurality of semiconductor chips 120. The support pads SP and the support wires SW may be provided in numbers less or more than those illustrated in the drawing. When the plurality of semiconductor chips 120 are the same type of semiconductor chips (for example, in a case where the plurality of semiconductor chips 120 are obtained from wafers fabricated by using the same set of designed masks (e.g. photomasks)), at least some of the plurality of semiconductor chips 120 may include support pads SP to which the support wires SW are not connected. The pair of support pads SP may include a first support pad SP1 and a second support pad SP2.

In the specification, the term “support wire” may be used in distinction from the term “bonding wire.” This distinction is intended to emphasize that the support wire refers to a subset of the bonding wires that are specifically configured to distribute mechanical stress applied to an upper chip (e.g., overhang portions of an upper chip among two chips). Similarly, the term “support pad” may be used in distinction from the term “bonding pad” (or “connection pad”), and this distinction is intended to emphasize that the support pad refers to a subset of the bonding pads that are specifically configured to distribute mechanical stress applied to an upper chip (e.g., overhang portions of an upper chip among two chips).

The first support pad SP1 may be disposed on the overhang portion of the top chip 120b. The first support pad SP1 may be adjacent to the overhang edge OVE of the top chip 120b. For example, the first support pad SP1 may be a dummy pad formed on the upper surface of the top chip 120b adjacent to the overhang edge OVE.

As used herein, the term “dummy” is used to refer to a component that has the same or similar structure and shape as other similarly named components but does not have a substantial function as such components. A dummy pad, e.g., may be a conductor having a similar shape and size as a normal pad but not be used as a terminal to transfer an electrical signal. In some examples, a dummy pad may be electrically floating.

The second support pad SP2 may be disposed on one of the plurality of semiconductor chips 120 or the substrate 110. The combination of the plurality of semiconductor chips 120 and the substrate 110 may include the second support pad SP2. For example, the second support pad SP2 may be included in or on the plurality of semiconductor chips 120 or in or on the substrate 110.

The first support pad SP1 may not overlap the stack chip 120a positioned directly below the top chip 120b among the plurality of stack chips 120a in the vertical direction Z. For example, the first support pad SP1 may not overlap an uppermost chip among the stack chips 120a in the vertical direction Z in the plan view. For example, the first support pads SP1 may be closer to the second edge EG2 than to the first edge EG1 in the horizontal direction X.

The second support pad SP2 may be spaced apart from the first support pad SP1 in a direction opposite to (or away from) the overhang edge OVE. In an embodiment, the second support pad SP2 may be disposed on a lower level than that of the first support pad SP1. The first support pad SP1 may be at a first height (e.g., height level) relative to the substrate 110, and the second support pad SP2 may be at a second height lower than the first height relative to the substrate 110. For example, the second support pad SP2 may be disposed on at least one of the plurality of stack chips 120a or the substrate 110. Through this, a load applied to the overhang portion of the top chip 120b may be more effectively distributed. For example, the second support pad SP2 may be a dummy pad.

The support wire SW may electrically and/or mechanically connect the first support pad SP1 and the second support pad SP2 to each other. However, in some embodiments, the support wire SW may be electrically connected to the first support pad SP1, while the support wire SW is not directly mechanically connected to (e.g., not in contact with) the first support pad SP1. In addition, each of the support wires SW may be directly connected to a corresponding one of the second support pads SP2.

As used herein, components described as being “electrically connected” are configured such that an electrical signal can be transferred from one component to the other (although such electrical signal may be attenuated in strength as it is transferred and may be selectively transferred).

The support wire SW may extend to the opposite side of the overhang edge OVE of the top chip 120b. As described later, during the process of bonding ends of the support wire SW to the support pads SP1, SP2 and SP3 (SP3 is described further below), mechanical forces may be applied to each support pad. In some embodiments, the bonding method may be designed to apply less force to the support pads SP1 and SP2 than to the support pad SP3. For example, the support wire SW may be first bonded to the first support pad SP1, and then bonded to the second support pad SP2 to minimize the load applied to the overhang edge OVE of the top chip 120b. For example, the support wire SW may include a ball portion BL contacting the first support pad SP1 and a stitch portion ST contacting the second support pad SP2.

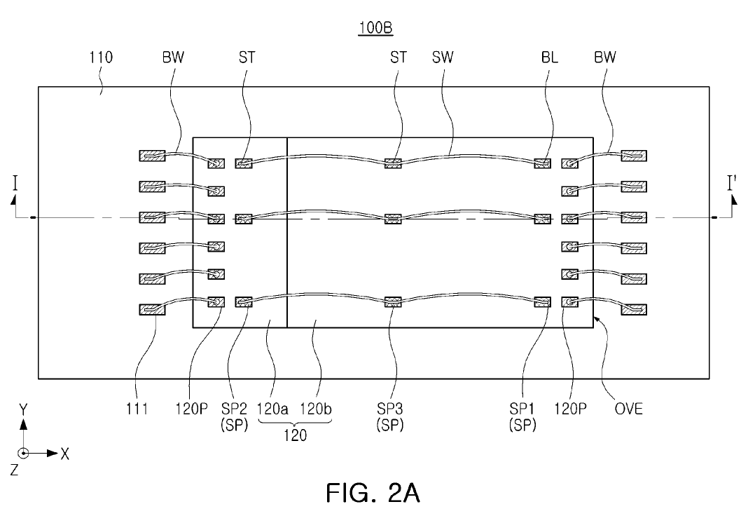

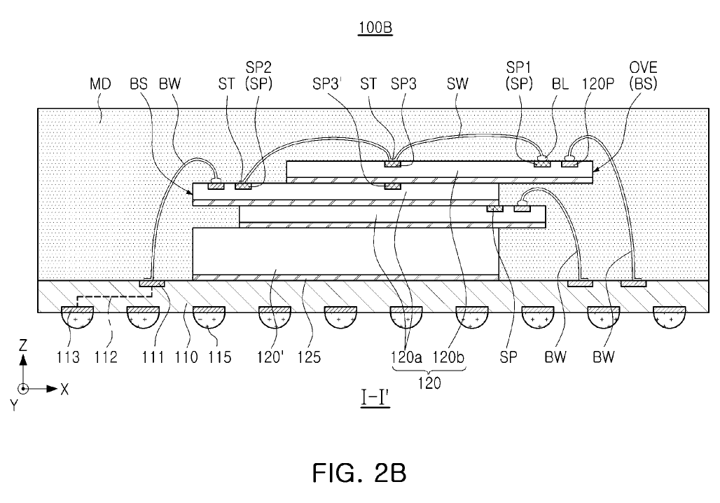

FIG. 2A is a plan view of a semiconductor package 100B according to an embodiment, and FIG. 2B is a cross-sectional view taken along line I-I’ of FIG. 2A.

Referring to FIGS. 2A and 2B, the semiconductor package 100B of the embodiment may include the same or similar features as those described above with reference to FIGS. 1A and 1B, except that the semiconductor package 100B further includes a third support pad SP3. The third support pad SP3 may be disposed on at least one of the plurality of stack chips 120a or the top chip 120b.

A chip of the same type as that of the chip (on which the third support pad SP3 is formed) among the plurality of semiconductor chips 120 may include a support pad, in which the support wire SW is not connected to a position corresponding to the third support pad SP3.

For example, the top chip 120b may include the third support pad SP3 as depicted in FIGS. 2A and 2B. In addition, in some embodiments, at least one of the plurality of stack chips 120a and the top chip 120b may be of the same type, the one of the plurality of stack chips 120a may include a pad SP3’ with which no bonding wire is in contact. In some embodiments, the plurality of stack chips 120a and the top chip 120b may be of the same type. For example, for example, the plurality of stack chips 120a and the top chip 120b may be semiconductor memory chips having the same size and the same functionality.

The third support pad SP3 may be positioned between the first support pad SP1 and the second support pad SP2. The third support pad SP3 may overlap at least one of the plurality of stack chips 120a in the vertical direction (Z direction). As shown in FIG. 2B, each of the third support pads SP3 may provide a contact point with which a pair of support wires SW are in contact. Accordingly, the pair of the support wires SW may provide a mechanical connection between the first support pad SP1 and the second support pad SP2. In some embodiments, the pair of support wires SW may electrically connect the first support pad SP1, the second support pad SP2, and the third support pad SP3. In some embodiments, the support wires SW, the first support pad SP1, the second support pad SP2, and the third support pad SP3 may be dummy wires or dummy pads. The support wire SW may further include the stitch portion ST contacting the third support pad SP3. Accordingly, the structural stability of the support wire SW may be improved, and the load applied to the overhang portion of the top chip 120b may be more effectively distributed, because the third support pad SP3, the plurality of stack chips 120a and the spacer die 120’ overlap one another in a plan view and/or are mechanically joined to each other by adhesive films 125.

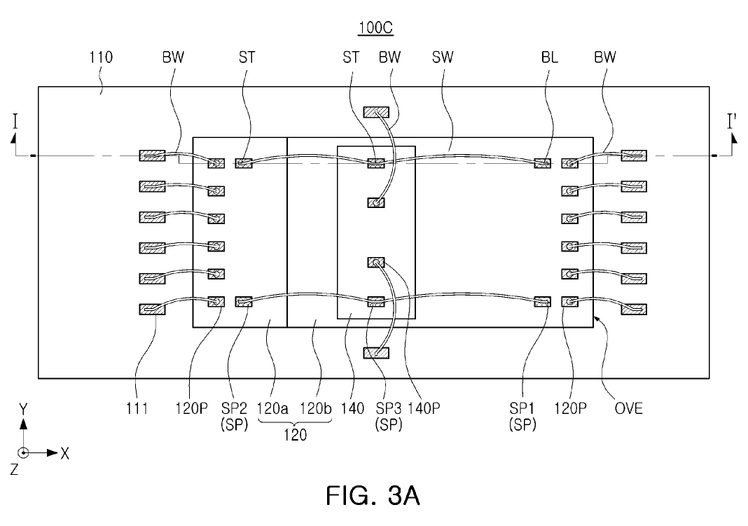

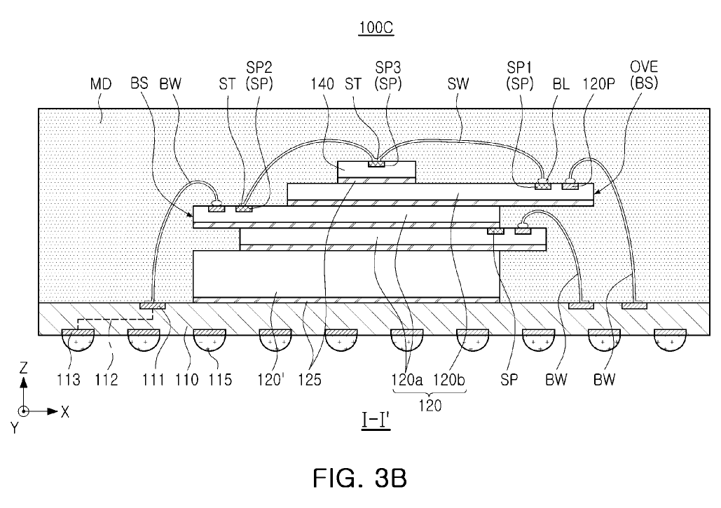

FIG. 3A is a plan view of a semiconductor package 100C according to an embodiment, and FIG. 3B is a cross-sectional view taken along line I-I’ of FIG. 3A.

Referring to FIGS. 3A and 3B, the semiconductor package 100C of the embodiment may include the same or similar features as those described above with reference to FIGS. 1A, 1B, 2A and 2B, except that the semiconductor package 100C further includes an intermediate chip 140.

The intermediate chip 140 may be a controller chip. The intermediate chip 140 may be a memory controller determining or controlling a data processing of the plurality of semiconductor chips 120 and preventing errors and bad sectors. In some embodiments, the intermediate chip 140 may include a dummy chip. In this case, the intermediate chip 140 may not include a connection pad 140P.

The intermediate chip 140 may be disposed on the top chip 120b. The intermediate chip 140 may be a chip smaller than the top chip 120b. The intermediate chip 140 may be located between the first support pad SP1 and the second support pad SP2. The intermediate chip 140 may include the connection pad 140P and the third support pad SP3. The connection pad 140P may be connected to the bonding pad 111 of the substrate 110 via the bonding wire BW.

The third support pad SP3 may provide a contact point with which a pair of support wires SW are in contact. Accordingly, the pair of support wires SW may provide a mechanical connection between the first support pad SP1 and the second support pad SP2. In some embodiments, the pair of support wires SW may electrically connect the first support pad SP1, the second support pad SP2, and the third support pad SP3. In some embodiments, the support wires SW, the first support pad SP1, the second support pad SP2, and the third support pad SP3 may be dummy wires or dummy pads. The support wire SW may further include the stitch portion ST contacting the third support pad SP3. Therefore, the structural stability of the support wire SW may be improved, and the load (or mechanical stress) applied to the overhang portion of the top chip 120b may be more effectively distributed.

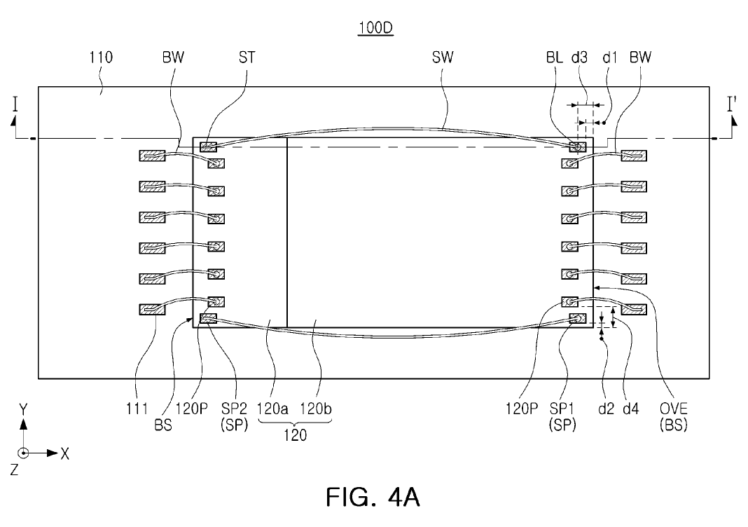

FIG. 4A is a plan view of a semiconductor package 100D according to an embodiment, and FIG. 4B is a cross-sectional view taken along line I-I’ of FIG. 4A.

Referring to FIGS. 4A and 4B, the semiconductor package 100D of the embodiment may include features that are the same as or similar to those described above with reference to FIGS. 1A, 1B, 2A, 2B 3A and 3B, except for the location of the support pad SP or except for certain features described below. The support pad SP may be closer to the edge (or the bonding side BS) of the semiconductor chip 120 than the connection pad 120P. For example, the support pad SP may be formed closer to a scribe lane of the semiconductor chip 120 than the connection pad 120P. For example, the connection pad 120P may be disposed in at least one row adjacent to the bonding side BS of the top chip 120b. In this case, the first support pad SP1 may be disposed at the end of the row of the connection pad 120P. A distance d1 between the first support pad SP1 and the overhang edge OVE may be smaller than a distance d3 between the connection pad 120P of the top chip 120b and the bonding side BS. In addition, in the direction Y, a distance d2 between one side (or an edge in a plan view) of the top chip 120b and the first support pad SP1 may be smaller than a distance d4 between the connection pad 120P of the top chip 120b and the one side. Similarly, the second support pad SP2 may be closer to the bonding side BS of the stack chip 120a than the connection pad 120P.

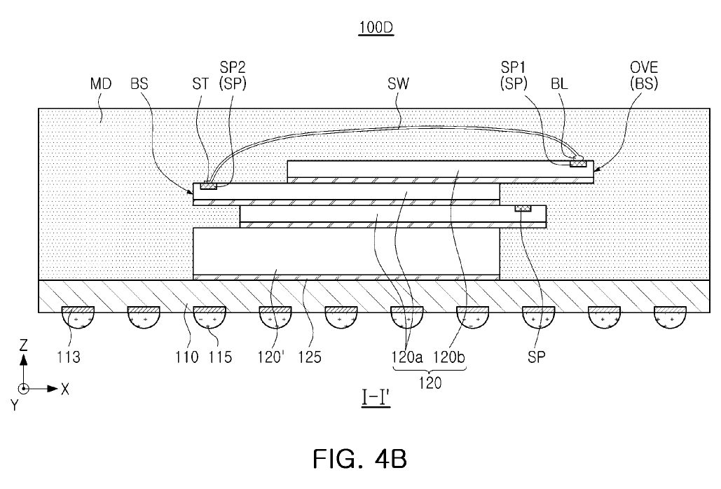

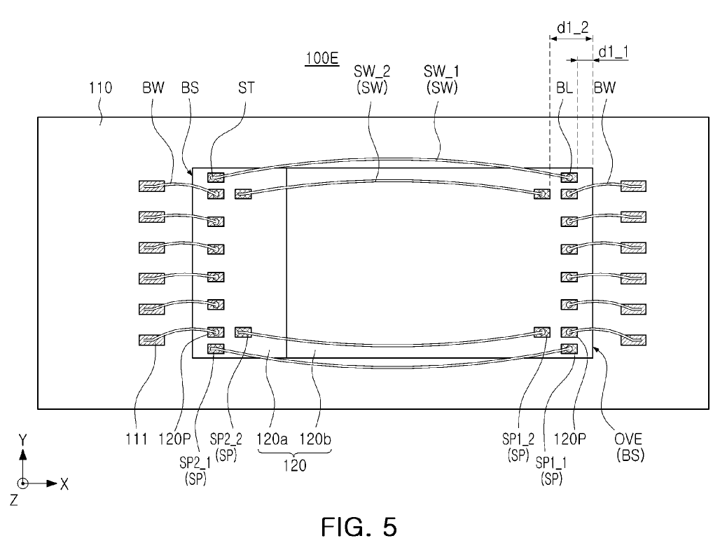

FIG. 5 is a plan view of a semiconductor package 100E according to an embodiment.

Referring to FIG. 5, the semiconductor package 100E of an embodiment may include the same or similar features as those described above with reference to FIGS. 1A, 1B, 2A, 2B, 3A, 3B, 4A and 4B, except for the arrangement of the support pads SP or except for certain features described below.

The support pads SP may include a plurality of groups of the support pads SP arranged around (or adjacent to) the connection pads 120P. The first group of first support pads SP1_1 and the second group of first support pads SP1_2 may be disposed at different distances from the overhang edge OVE. The first group of first support pads SP1_1 may be spaced apart in the direction X by a first distance d1_1 from the overhang edge OVE. The first distance d1_1 may be equal to or smaller than the distance between the connection pad 120P and the bonding side BS. The second group of first support pads SP1_2 may be spaced apart in the direction X by a second distance d1_2 greater than the first distance d1_1 from the overhang edge OVE.

The first group of second support pads SP2_1 and the second group of second support pads SP2_2 may be spaced apart in the direction X by different distances from the edge (for example, the bonding side BS) of the stack chip 120a. The first group of second support pads SP2_1 may be spaced apart in the direction X by a first distance from the bonding side BS of the stack chip 120a. The first distance may be smaller than the distance between the connection pad 120P and the bonding side BS. The second group of second support pads SP2_2 may be spaced apart in the direction X by a second distance greater than the first distance from the edge (for example, the bonding side BS) of the stack chip 120a.

The support wires SW may include first support wires SW1 connecting the first group of first support pads SP1_1 to the first group of second support pads SP2_1 and second support wires SW2 connecting the second group of first support pads SP1_2 to the second group of second support pads SP2_2. The first group of first support pads SP1_1 and the first group of second support pads SP2_1 may be disposed in positions corresponding to each other with the shortest distance. The second group of first support pads SP1_2 and the second group of second support pads SP2_2 may be disposed in positions corresponding to each other with the shortest distance. For example, the first group of first support pads SP1_1 and the first group of second support pads SP2_1 may be positioned symmetrically in a plan view with respect to a line extending parallel to the direction Y. For example, the second group of first support pads SP1_2 and the second group of second support pads SP2_2 may be positioned symmetrically in a plan view with respect to a line extending parallel to the direction Y. In this manner, the support pads SP and the support wires SW may be disposed in various manners in consideration of the stack structure of the plurality of semiconductor chips 120, the load applied to the top chip 120b, or the like.

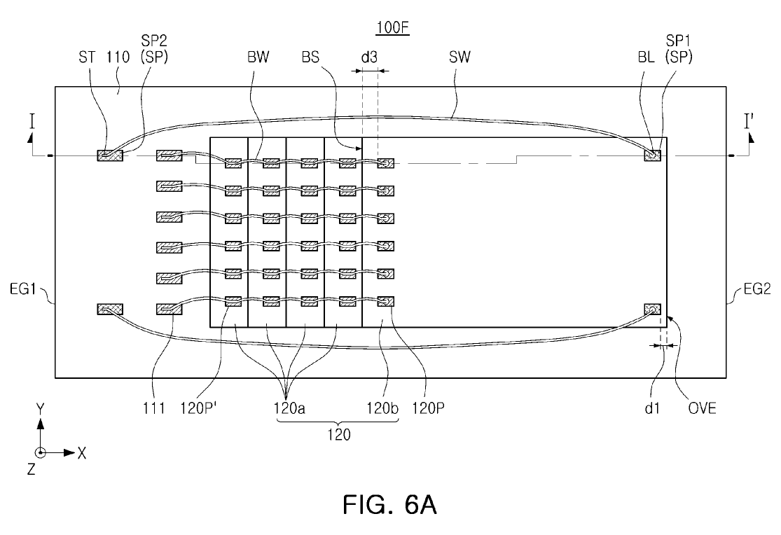

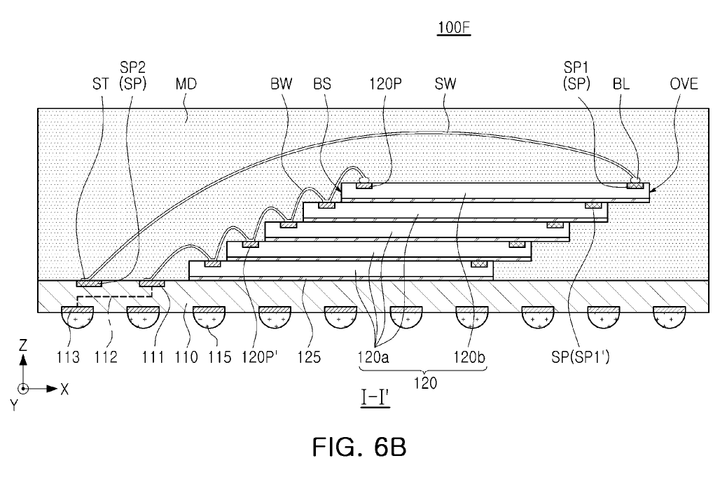

FIG. 6A is a plan view of a semiconductor package 100F according to an embodiment, and FIG. 6B is a cross-sectional view taken along line I-I’ of FIG. 6A.

Referring to FIGS. 6A and 6B, the semiconductor package 100F of an embodiment may include the same or similar features as those described above with reference to FIGS. 1A, 1B, 2A, 2B, 3A, 3B, 4A, 4B and 5, except for certain features described below.

In the present embodiment, the plurality of semiconductor chips 120 may be stacked so that each of the connection pads 120P is horizontally offset. Accordingly, the connection pads 120P are exposed to (or in contact with) the molding layer MD and the bonding sides BS, on which the connection pads 120P, are arranged to face in the same direction. The plurality of semiconductor chips 120 may be stacked so that each of the bonding sides BS faces one end (or edge) of the substrate 110. In this case, the bonding side BS (or connection pads 120P) of the top chip 120b may be located on the opposite side of the overhang edge OVE in a plan view.

The bonding side BS of the stack chips 120a arranged below the top chip 120b may face in the same direction as the bonding side BS of the top chip 120b. For example, the pads 120P’ of the stack chips 120a may be arranged adjacent to the bonding side BS. The pads 120P’ of the stack chips 120a may correspond to the pads 120P of the top chip 120b. The pads 120P’ of the stack chips 120a and the bonding side BS of the top chip 120b may be closer to the first edge EG1 than to the second edge EG2 in the horizontal direction X in a plan view.

The first support pads SP1 may be closer to the second edge EG2 of the semiconductor chip 120 than the connection pads 120P. The connection pads 120P may be arranged in at least one row adjacent to the bonding side BS of the top chip 120b. The first support pads SP1 may be disposed to be adjacent to the overhang edge OVE opposite to the bonding side BS. The distance d1 between the first support pads SP1 and the overhang edge OVE may be smaller than the distance d3 between the connection pads 120P of the top chip 120b and the bonding side BS. The second support pads SP2 may be disposed to be adjacent to the first edge EG1 of the substrate 110, toward which the bonding sides BS of the plurality of semiconductor chips 120 face. Each second support pad SP2 may be a dummy pad formed on the upper surface of the substrate 110. For example, the pads sp1 and sp2 may be dummy pads.

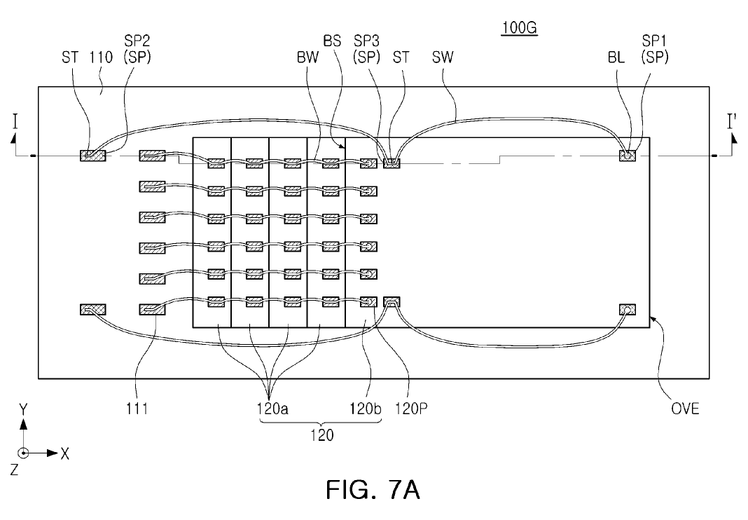

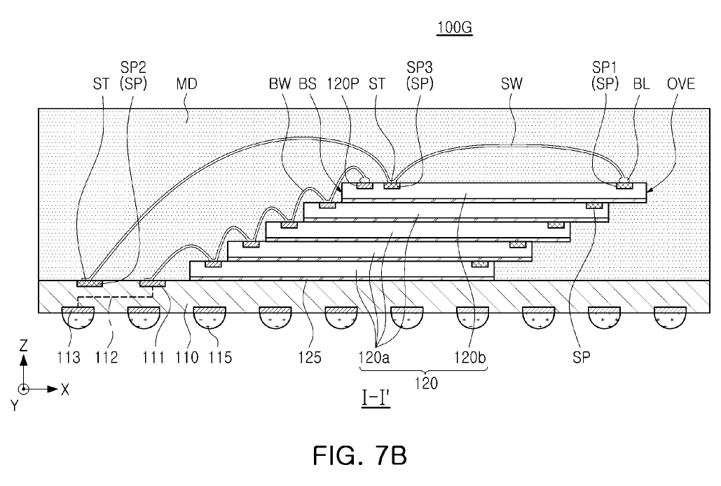

FIG. 7A is a plan view of a semiconductor package 100G according to an embodiment, and FIG. 7B is a cross-sectional view taken along line I-I’ of FIG. 7A.

Referring to FIGS. 7A and 7B, the semiconductor package 100G of an embodiment may include the same or similar features as those described above with reference to FIGS. 1A, 1B, 2A, 2B, 3A, 3B, 4A, 4B, 5, 6A and 6B, except for certain features described below. The third support pads SP3 may be disposed to be adjacent to the bonding side BS of the top chip 120b. The third support pads SP3 may be disposed near the row of the connection pads 120P. As shown in the drawing, the third support pad SP3 is positioned farther from the bonding side BS than the connection pad 120P, but in some embodiments, the third support pads SP3 may be positioned closer to the bonding side BS than the connection pads 120P. The third support pad SP3 may be positioned between the first support pad SP1 and the second support pad SP2. The third support pad SP3 may overlap at least one of the plurality of stack chips 120a in the vertical direction (the Z direction). The third support pad SP3 may provide a contact point with which a pair of support wires SW are in contact. Accordingly, the pair of support wires may provide a mechanical connection SW between the first support pad SP1 and the second support pad SP2. In some embodiments, the pair of support wires SW may electrically connect the first support pad SP1, the second support pad SP2, and the third support pad SP3. In some embodiments, the support wires SW, the first support pad SP1, the second support pad SP2, and the third support pad SP3 may be dummy wires or dummy pads. The support wire SW may further include the stitch portion ST in contact with the third support pad SP3. Therefore, the structural stability of the support wire SW may be improved, and the load applied to the overhang portion of the top chip 120b may be more effectively distributed.

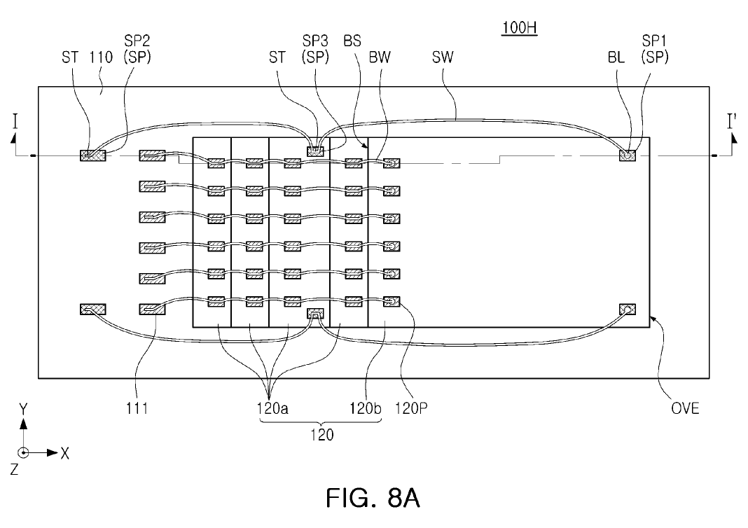

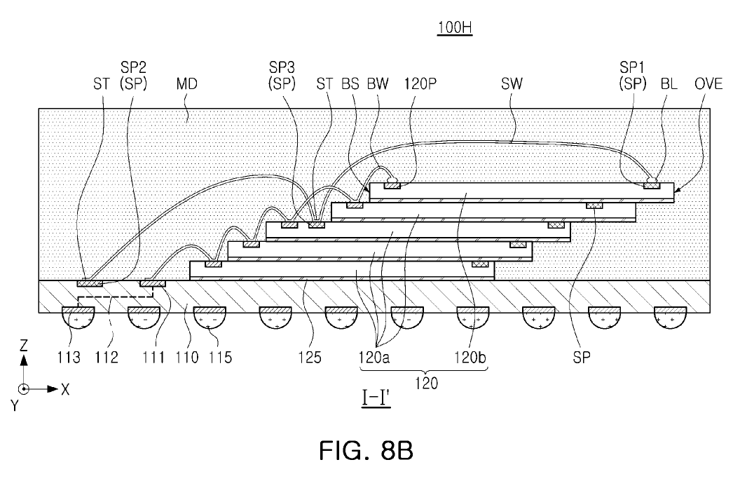

FIG. 8A is a plan view of a semiconductor package 100H according to an embodiment, and FIG. 8B is a cross-sectional view taken along line I-I’ of FIG. 8A.

Referring to FIGS. 8A and 8B, the semiconductor package 100H of the embodiment may include the same or similar features as those described above with reference to FIGS. 1A, 1B, 2A, 2B, 3A, 3B, 4A, 4B, 5, 6A, 6B, 7A and 7B, except for certain features described below. The third support pad SP3 may be disposed on one of the plurality of stack chips 120a. Among the plurality of semiconductor chips 120, a chip of the same type as the chip (on which the third support pad SP3 is formed) may include a support pad, to which the support wire SW is not connected in a position corresponding to the third support pad SP3. The third support pads SP3 may be adjacent to the bonding side BS of the stack chip 120a. The third support pads SP3 may be positioned to avoid an electrical short of the bonding wire BW and the support wire SW. As shown in the drawing, third support pads SP3 are positioned at both (or opposite) ends of the row of the connection pads 120P to prevent short of the support wire SW, but the position of the third support pads SP3 are not limited thereto. The third support pads SP3 may be positioned between the first support pads SP1 and the second support pads SP2. The third support pad SP3 may provide a contact point with which a pair of support wires SW are in contact. Accordingly, the pair of support wires SW may provide a mechanical connection between the first support pad SP1 and the second support pad SP2. In some embodiments, the pair of support wires SW may electrically connect the first support pad SP1, the second support pad SP2, and the third support pad SP3. In some embodiments, the support wires SW, the first support pad SP1, the second support pad SP2, and the third support pad SP3 may be dummy wires or dummy pads. The support wire SW may further include the stitch portion ST in contact with the third support pad SP3. Accordingly, the structural stability of the support wire SW may be improved, and the load applied to the overhang portion of the top chip 120b may be distributed more effectively.

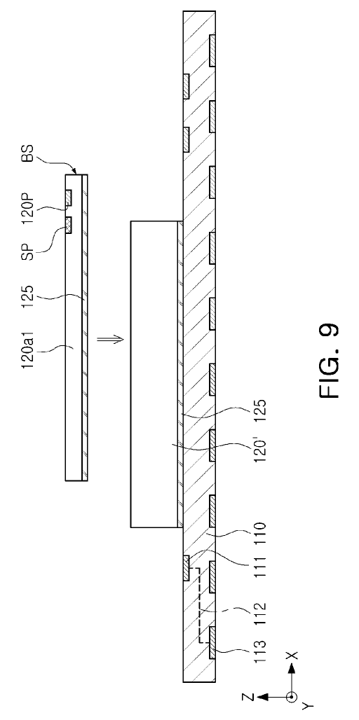

FIGS. 9 to 15 are diagrams illustrating a method of manufacturing a semiconductor package according to an embodiment.

Referring to FIG. 9, a spacer die 120’ may be attached on the substrate 110. Though not shown in the drawings, the substrate 110 may be a part of a strip substrate (e.g., a plurality of substrates in strip form) in which a plurality of unit substrates are connected. The spacer die 120’ may be a silicon dummy having a designed (or predetermined) thickness. Thereafter, a first semiconductor chip 120a1 may be attached on the spacer die 120’. The first semiconductor chip 120a1 may include the connection pads 120P and the support pads SP adjacent to the bonding side BS. The first semiconductor chip 120a1 may be disposed such that the bonding side BS faces a first end (or edge) of the substrate 110. The spacer die 120’ and the first semiconductor chip 120a1 may be attached using an adhesive film 125.

Referring to FIG. 10, the first semiconductor chip 120a1 may be connected to the substrate 110 by a wire bonding process. A first bonding wire BW1 electrically connecting the first semiconductor chip 120a1 to the substrate 110 may be formed. The first bonding wire BW1 may electrically connect the connection pad 120P of the first semiconductor chip 120a1 to the bonding pad 111 of the substrate 110. The first bonding wire BW1 may include, but is not limited to, gold (Au) or alloys thereof.

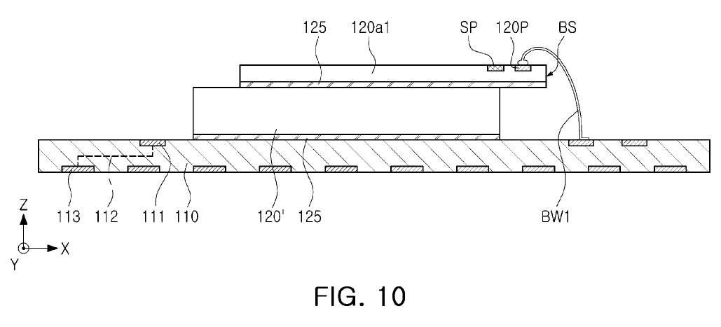

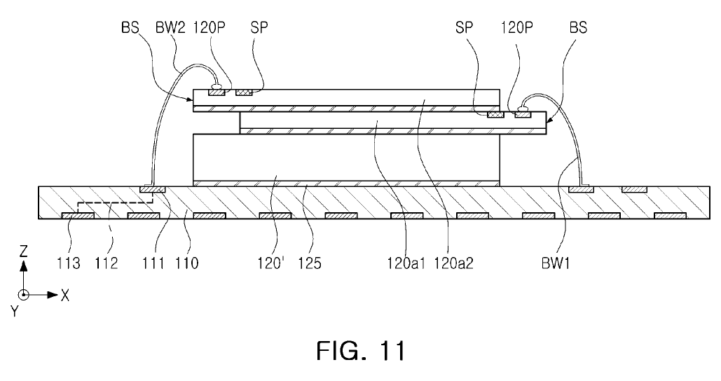

Referring to FIG. 11, a second semiconductor chip 120a2 may be disposed. The second semiconductor chip 120a2 may be disposed on the first semiconductor chip 120a1. The second semiconductor chip 120a2 may be an integrated circuit chip of the same type as the first semiconductor chip 120a1. The second semiconductor chip 120a2 may include the connection pad 120P adjacent to the bonding side BS and the support pad SP. The second semiconductor chip 120a2 may be disposed such that the bonding side BS faces the opposite side of the bonding side BS of the first semiconductor chip 120a1. For example, the second semiconductor chip 120a2 may be disposed to face a second end (or edge) of the substrate 110. Thereafter, the second semiconductor chip 120a2 may be connected to the substrate 110 by a wire bonding process. The second bonding wire BW2 may electrically connect the connection pad 120P of the second semiconductor chip 120a2 to the bonding pad 111 of the substrate 110. Although not illustrated in the drawing, a stacking process of the first semiconductor chip 120a1 and the second semiconductor chip 120a2 may be repeated several times to form a chip stack in which three or more semiconductor chips are stacked.

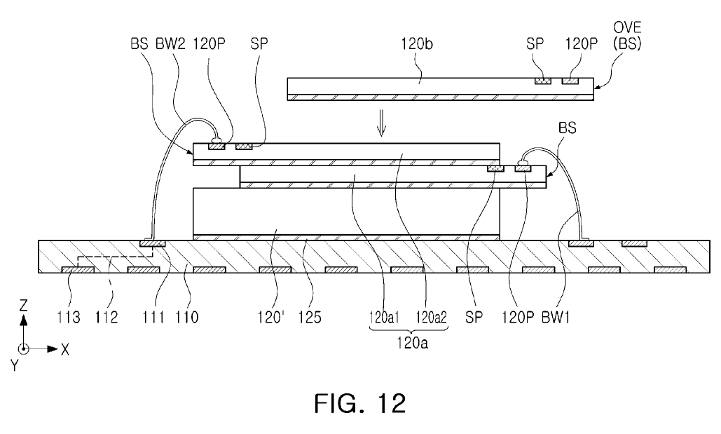

Referring to FIG. 12, the top chip 120b may be disposed on a plurality of stack chips 120a. The top chip 120b may include the connection pad 120P and the support pad SP. The top chip 120b may be shifted in one direction (e.g., the horizontal direction X) with respect to the chip 120a1 and/or the chip 120a so that an edge portion of the top chip 120b has an overhang configuration adjacent to the support pads SP. For example, the top chip 120b may be stacked on the plurality of stack chips 120a with a horizontal offset, such that a portion of the top chip 120b protrudes beyond at least one of the plurality of stack chips 120a to form an overhang. The top chip 120b may include the overhang edge OVE protruding outwardly (or away) from the plurality of stack chips 120a. For example, the overhang edge OVE of the top chip 120b may protrude, as compared to the edge of the stack chip 120a facing in the same direction, for example, the bonding side BS of the first semiconductor chip 120a1. For example, the overhang edge OVE of the top chip 120b may protrude beyond an edge of the stack chip 120a in the horizontal direction X. For example, the overhang edge OVE and the bonding side BS of the first semiconductor chip 120a1 may face toward the same direction.

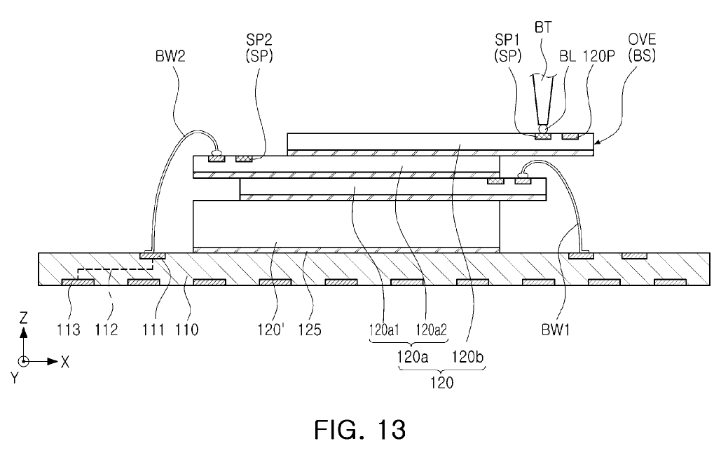

Referring to FIG. 13, a ball bonding (or ball portion) BL may be formed on the support pad SP of the top chip 120b. The ball portion BL may be formed on the first support pad SP1 adjacent to the overhang edge OVE of the top chip 120b. The ball portion BL may be formed in a manner for minimizing the load (or mechanical stress) applied to the overhang portion of the top chip 120b. The ball portion BL may be bonded to the first support pad SP1 by a thermocompression method, an ultrasonic method, or a thermoultrasonic method using a bonding tool BT (e.g., a capillary).

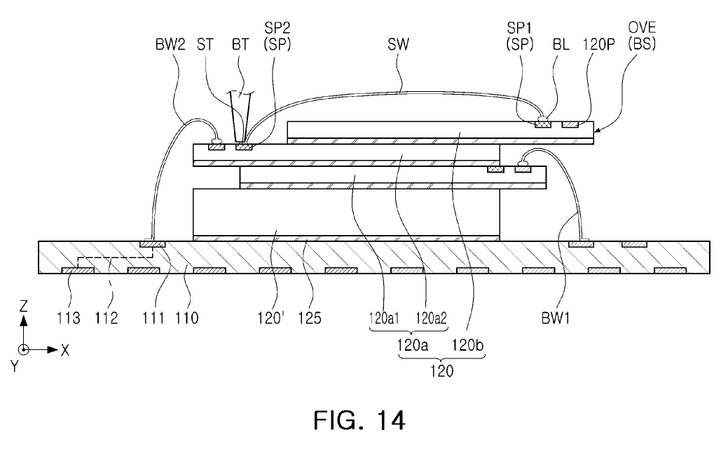

Referring to FIG. 14, a stitch bonding (or stitch portion) ST may be formed on the support pad SP of the stack chip 120a. For example, the stitch portion ST of the support wire SW may be formed on the second support pad SP2 of the second semiconductor chip 120a2. The stitch portion ST may be positioned on one side of the stack chip 120a. On the one side of the stack chip 120a, the support pads SP may be disposed. The one side of the stack chip 120a may face opposite to the overhang edge OVE of the top chip 120b. In order to minimize the load applied to the overhang portion of the top chip 120b, the support wire SW may be ball-bonded to the first support pad SP1 and stitch-bonded to the second support pad SP2. The support wire SW may extend from the first support pad SP1. The support wire SW may extend away from the overhang edge OVE and fixed (or bonded) to the second support pad SP2, thereby distributing the load applied to the overhang portion of the top chip 120b.

Referring to FIG. 15, the top chip 120b may be connected to the substrate 110 by a wire bonding process. The third bonding wire BW3 may electrically connect the connection pad 120P of the top chip 120b to the bonding pad 111 of the substrate 110. The support wire SW may support the overhang portion of the top chip 120b in the process of forming the third bonding wire BW3 to distribute the load (or mechanical stress) and prevent sagging and cracking. For example, the mechanical stress may be induced by the operation of the capillary during the process of forming the third bonding wire BW3. For example, the support wire SW may mechanically hold the overhang portion of the chip 120b, during the process of forming the third bonding wire BW3, thereby reducing the mechanical stress applied to the overhang portion of the chip 120b.

In some embodiments, when the plurality of semiconductor chips 120 are arranged to face in one direction (the embodiment of FIGS. 6A to 8B), the bonding wires BW1, BW2, and BW3 may be formed collectively before and after the formation of the support wire SW. Thereafter, after the molding layer and the connecting bumps are formed, a sawing process may be performed to separate unit packages. For example, in some embodiments, in a manufacturing process for a semiconductor package corresponding to the embodiments described with respect to FIGS. 6A, 7A and 8B, the plurality of the support wires SW connected to all the chips 120 in the package may be formed before connecting all the plurality of the bonding wires BW to the chips 120. In other embodiments, the plurality of the support wires SW connected to all the chips 120 in the package may be formed after connecting all the plurality of the bonding wires BW to the chips 120.

According to the embodiments of the present inventive concept, a semiconductor package may include: a substrate (e.g., 110 in FIG. 1B) including first bonding pads (e.g., 111 in FIG. 1B), the substrate including a first edge (e.g., EG1 in FIG. 1A) and a second edge (e.g., EG2 in FIG. 1A) which are spaced apart from each other in a horizontal direction in a plan view; a plurality of first chips (e.g., 120a in FIG. 1B) stacked on the substrate; a second chip (e.g., 120b in FIG. 1B) stacked on the plurality of first chips, the second chip including a third edge (e.g., BS in FIG. 1B) protruding away from the plurality of first chips in the horizontal direction in the plan view; a second bonding pad (e.g., SP1 in FIG. 1B) disposed on the second chip and adjacent to the third edge; a third bonding pad disposed on one of the plurality of first chips or on the substrate and spaced apart from the second bonding pad in the horizontal direction in the plan view, the third bonding pad being closer to the first edge than to the second edge in the horizontal direction in the plan view; a first bonding wire (e.g., SW in FIG. 1B) in contact with the second bonding pad; and second bonding wires (e.g., BW in FIG. 1B), each of the second bonding wires electrically connected to a corresponding one of the first bonding pads, the second bonding pad being closer to the second edge than to the first edge in the horizontal direction in the plan view. The first bonding wire may be directly connected to the third bonding pad, each of the plurality of first chips includes a fourth bonding pad (e.g., 120P in FIG. 1A), and the second bonding wires may be respectively electrically connected to the fourth bonding pads.

In some embodiment, the second chip may include a second bonding pad (e.g., SP1 in FIG. 1B) located adjacent to the third edge, a first bonding wire (e.g., SW in FIG. 1B) may be in contact with the second bonding pad, and second bonding wires (e.g., BW in FIG. 1B).

In some embodiments, the semiconductor package may further include a fifth bonding pad (e.g., SP3 in FIGS. 2B, 3B, 7B or 8B) disposed on the second chip or the one of the plurality of first chips and located between the second bonding pad and the third bonding pad, and the first bonding wire may be in contact with the fifth bonding pad.

In some embodiments, the semiconductor package may further include a third chip (e.g., 140 in FIG. 3B) disposed on the second chip and located between the second bonding pad and the third bonding pad in the plan view. The third chip may include fifth bonding pads (e.g., SP3 in FIG. 3B), and the first bonding wire may be in contact with a corresponding one of the fifth bonding pad.

In some embodiments, the semiconductor package may further include a third bonding wire (e.g., BW in FIG. 3A). The third chip may be a controller chip, the third bonding wire may electrically connect the third chip to a corresponding one of the first bonding pads of the substrate, and the third bonding wire is in contact with a corresponding one of the fifth bonding pad (e.g., SP3 in FIG. 3B).

In some embodiments, the second chip may further include fifth bonding pads (e.g., 120P in FIG. 4A), the fifth bonding pads are arranged in a row, the fifth bonding pads are arranged adjacent to one edge of the second chip, and a distance between the second bonding pad and the third edge of the second chip is smaller than a distance between the fifth bonding pads of the second chip and the one edge of the second chip.

In some embodiments, the semiconductor package may further include: a fifth bonding pad (e.g., SP1_1 in FIG. 5) disposed on the second chip and adjacent to the third edge; and a sixth bonding pad (e.g., SP2_1 in FIG. 5) disposed on one of the plurality of first chips or on the substrate and spaced apart from the fifth bonding pad in the horizontal direction in the plan view, the sixth bonding pad being closer to the first edge than to the second edge in the horizontal direction in the plan view. The semiconductor package may further include a third bonding wire (e.g., SW_1 in FIG. 5) in contact with the fifth bonding pad. In the horizontal direction in the plan view, the fifth bonding pads may be arranged at a first distance from the third edge of the second chip, and the second bonding pad (e.g., SP1_1 in FIG. 5) may be arranged at a second distance from the third edge of the second chip, the first distance and the second distance may be different. The third bonding wire may be directly connected to the sixth bonding pad.

According to the embodiments of the present inventive concept, by distributing the load applied to the overhang portion of the top chip, the semiconductor package with improved reliability may be provided.

While embodiments have been illustrated and described above, it will be apparent to those skilled in the art, upon having reviewed and understood this specification and the appended claims, that modifications and variations could be made without departing from the scope of the present inventive concept.

What is claimed is:

1. A semiconductor package comprising:
a substrate including first bonding pads, the substrate including a first edge and a second edge which are spaced apart from each other in a horizontal direction in a plan view;
a plurality of first chips stacked on the substrate;
a second chip stacked on the plurality of first chips and including a third edge protruding away from the plurality of first chips in the horizontal direction in the plan view;
a second bonding pad disposed on the second chip and adjacent to the third edge, the second bonding pad being closer to the second edge than to the first edge in the horizontal direction in the plan view;
a third bonding pad disposed on one of the plurality of first chips or on the substrate and spaced apart from the second bonding pad in the horizontal direction in the plan view, the third bonding pad being closer to the first edge than to the second edge in the horizontal direction in the plan view;
a first bonding wire in contact with the second bonding pad; and
second bonding wires, each of the second bonding wires electrically connected to a corresponding one of the first bonding pads,
wherein:
the first bonding wire is directly connected to the third bonding pad,
each of the plurality of first chips includes a fourth bonding pad, and
the second bonding wires are respectively electrically connected to the fourth bonding pads.

2. The semiconductor package of claim 1, wherein the first bonding wire includes a ball portion contacting the second bonding pad and a stitch portion contacting the third bonding pad.

3. The semiconductor package of claim 1, wherein:
the plurality of first chips includes an uppermost chip that is positioned immediately below the second chip in a vertical direction, and
the second bonding pad does not overlap the uppermost chip in the vertical direction in the plan view.

4. The semiconductor package of claim 1, wherein each of the fourth bonding pads is one of a signal pad, a power pad, or a ground pad, and
the second and third bonding pads are electrically insulated from the fourth bonding pads.

5. The semiconductor package of claim 1, further comprising a fifth bonding pad disposed on the second chip or the one of the plurality of first chips and located between the second bonding pad and the third bonding pad,
wherein the first bonding wire is in contact with the fifth bonding pad.

6. The semiconductor package of claim 5, wherein the fifth bonding pad overlaps the one of the plurality of first chips in a vertical direction.

7. The semiconductor package of claim 1, further comprising:
a third chip disposed on the second chip and located between the second bonding pad and the third bonding pad in the plan view,
wherein the third chip includes fifth bonding pads, and
wherein the first bonding wire is in contact with a corresponding one of the fifth bonding pads.

8. The semiconductor package of claim 7, further comprising a third bonding wire, wherein:
the third chip is a controller chip,
the third bonding wire electrically connects the third chip to a corresponding one of the first bonding pads of the substrate, and
the third bonding wire is in contact with a corresponding one of the fifth bonding pads.

9. The semiconductor package of claim 1, wherein:
the second chip includes fifth bonding pads,
the fifth bonding pads are arranged in a row,
the fifth bonding pads are arranged adjacent to one edge of the second chip, and
a distance between the second bonding pad and the third edge of the second chip is smaller than a distance between the fifth bonding pads of the second chip and the one edge of the second chip.

10. The semiconductor package of claim 1,
wherein:
in the horizontal direction in the plan view, the second bonding pad is one of a plurality of second bonding pads that include a first group of the second bonding pads arranged at a first distance from the third edge of the second chip, and a second group of the second bonding pads arranged at a second distance from the third edge of the second chip, and
the first distance and the second distance are different.

11. The semiconductor package of claim 10,
wherein in the horizontal direction in the plan view, the third bonding pad is one of a plurality of third bonding pads that include a first group of the third bonding pads corresponding to the first group of the second bonding pads and a second group of the third bonding pads corresponding to the second group of the second bonding pads,
wherein:
the first bonding wire includes a first group of wires in contact with the first group of the second bonding pads, and a second group of wires in contact with the second group of the second bonding pads,
the first group of wires is directly connected to the first group of the third bonding pads, and
the second group of wires is directly connected to the second group of the third bonding pads.

12. The semiconductor package of claim 1, wherein the second chip and the plurality of first chips are stacked with horizontal offsets in alternating directions so that the second chip and the plurality of first chips protrude partially relative to adjacent ones of the second chip and the plurality of first chips.

13. The semiconductor package of claim 12, further comprising a molding layer disposed on the substrate,
wherein each fourth bonding pad arranged on one side of each of the plurality of first chips is in contact with the molding layer.

14. The semiconductor package of claim 12, wherein each of the second chip and each of the plurality of first chips has an overhang portion, and
in the horizontal direction, a length of the overhang portion of the second chip is greater than a length of the overhang portion of each of the plurality of first chips.

15. The semiconductor package of claim 1, further comprising a dummy chip disposed between the plurality of first chips and the substrate,
wherein, in a vertical direction, a thickness of the dummy chip is greater than a thickness of each of the plurality of first chips, and
wherein the second bonding pad does not overlap the dummy chip in the plan view.

16. The semiconductor package of claim 1, wherein the second bonding pad and the third bonding pad are dummy pads.

17. A semiconductor package comprising:
a substrate including a bonding pad;
a plurality of semiconductor chips stacked on the substrate and respectively including a connection pad;
a bonding wire connecting the connection pad to the bonding pad;
a combination of the plurality of semiconductor chips and the substrate includes a pair of support pads;
a support wire connecting the pair of support pads; and
a molding layer covering the plurality of semiconductor chips,
wherein the pair of support pads includes:
a first support pad at a first height level relative to the substrate; and
a second support pad at a second height level lower than the first height level relative to the substrate.

18. The semiconductor package of claim 17, wherein the first support pad is adjacent to an edge of an overhang portion of an uppermost semiconductor chip among the plurality of semiconductor chips.

19. A semiconductor package comprising:
a substrate;
a plurality of stack chips on the substrate;
a top chip on the plurality of stack chips, the top chip including a first overhang portion;
a first support pad positioned on the first overhang portion of the top chip;
a second support pad on one of the plurality of stack chips or on the substrate;
a support wire connecting the first support pad to the second support pad; and
a bonding wire electrically connecting the plurality of stack chips and the top chip to the substrate.

20. The semiconductor package of claim 19, wherein the support wire extends from the first support pad in a direction away from the first overhang portion.
